(19) United States
(12) Patent Application Publication
(10) Pub. No.: US 2026/0322336 A1
(43) Pub. Date: Oct. 15, 2026

(54) HALF-BRIDGE RAIL BALANCER CIRCUIT

(71) Applicant: Crestron Electronics, Inc., Rockleigh, NJ (US)

(72) Inventor: Robert Buono, Mahwah, NJ (US)

(73) Assignee: Crestron Electronics, Inc., Rockleigh, NJ (US)

(21) Appl. No.: 19/467,211

(22) Filed: Feb. 2, 2026

Related U.S. Application Data
(60) Provisional application No. 63/753,066, filed on Feb. 3, 2025.

(51) Int. Cl. H03F 1/52; H03F 3/217

(52) U.S. Cl. CPC H03F 1/523; H03F 3/2171; H03F 2200/426

(57) ABSTRACT

Provided herein is a high voltage rail balancer circuit for use in a class D amplifier adapted to sense an imbalance between a positive high voltage power supply and a negative high voltage power supply. The rail balancer circuit comprises a first MOSFET switch connected to the positive high voltage power supply, a second MOSFET switch connected to the negative high voltage supply, and a first resistor-diode circuit adapted to change the first MOSFET switch from a conducting state to a non-conducting state faster than the second MOSFET switch can change from a non-conducting state to a conducting state, and a second resistor-diode circuit adapted to change the second MOSFET switch from a conducting state to a non-conducting state faster than the first MOSFET switch can change from a non-conducting state to a conducting state, such that cross conduction between the first and second MOSFET switches is substantially prevented.

### BACKGROUND

### Technical Field

Aspects of the embodiments relate to digital amplifiers and more particularly to systems, methods, and modes for mitigating over-voltage situations in Class-D amplifiers.

### Background Art

A Class-D amplifier is an electronic amplifier in which transistors operate as electronic switches that rapidly alternate between conductive and nonconductive states. The analog signal to be amplified is converted to a stream of pulses. Pulse conversion can be accomplished using pulse width modulation, pulse density modulation, or by another method. After amplification, the output pulse stream is converted back to an analog signal by passing it through a passive low pass filter. Passive low pass filters are commonly comprised of inductors and capacitors. One advantage of Class-D amplifiers is that they are typically more efficient than analog/linear amplifiers because less power is dissipated as heat.

However, problems arise with Class-D amplifiers that comprise a half-bridge circuit topology and a positive and a negative power supply rail. For example, over-voltage induced on one of the power supply rails can damage components if the rated voltage limits for those components are exceeded. Over-voltage is common as an operating characteristic of Class-D amplifiers that use a half-bridge circuit topology and a positive and negative power supply rail.

The half-bridge circuit topology allows energy drawn from one of the two power supply rails to be dumped into the opposite polarity power supply rail. When this occurs, the rail to which energy is pumped will increase in voltage, and, if the energy into that rail exceeds the energy drawn from that rail, the rail voltage will continue to increase causing an over-voltage condition. The problem is exacerbated by higher output power levels, and lower audio output frequencies.

Others have attempted solutions to these problems. One such attempted solution has been to increase the capacitance of the rail capacitors. This modification adds more components and cost, uses valuable physical space, and adds weight. Another attempted solution has been to utilize a full-bridge circuit topology for the amplifier instead of half-bridge circuit topology. This latter modification also suffers from increased parts count, as well as other negative factors.

Accordingly, a need has arisen for systems, methods, and modes for mitigating over-voltage situations in Class-D amplifiers.

### SUMMARY

It is an object of the embodiments to substantially solve at least the problems and/or disadvantages discussed above, and to provide at least one or more of the advantages described below.

It is therefore a general aspect of the embodiments to provide systems, methods, and modes for mitigating over-voltage situations in Class-D amplifiers that will obviate or minimize problems of the type previously described.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Further features and advantages of the aspects of the embodiments, as well as the structure and operation of the various embodiments, are described in detail below with reference to the accompanying drawings. It is noted that the aspects of the embodiments are not limited to the specific embodiments described herein. Such embodiments are presented herein for illustrative purposes only. Additional embodiments will be apparent to persons skilled in the relevant art(s) based on the teachings contained herein.

According to a first aspect of the embodiments, a high voltage rail balancer circuit is provided, for use in a class D amplifier, and adapted to sense an imbalance between a positive high voltage power supply and a negative high voltage power supply, the high voltage rail balancer circuit comprising: a first N-channel metal oxide semiconductor field effect transistor switch (first MOSFET switch) comprising a source terminal electrically connected to the positive high voltage power supply; a second N-channel metal oxide semiconductor field effect transistor switch (second MOSFET switch) comprising a source terminal electrically connected to the negative high voltage power supply; a first resistor-diode circuit; a second resistor-diode circuit; a three-winding transformer adapted to receive a substantially equal duty cycle switching signal and which is further adapted to simultaneously drive the first MOSFET switch to a conducting state and to drive the second MOSFET switch to a non-conducting state, and to simultaneously drive the second MOSFET switch to a conducting state and to drive the first MOSFET switch to a non-conducting state, and wherein the first resistor-diode circuit is adapted to change the first MOSFET switch from a conducting state to a non-conducting state faster than the second MOSFET switch can change from a non-conducting state to a conducting state, and the second resistor-diode circuit is adapted to change the second MOSFET switch from a conducting state to a non-conducting state faster than the first MOSFET switch can change from a non-conducting state to a conducting state, such that cross conduction between the first and second MOSFET switches is substantially prevented.

According to a second aspect of the embodiments, a high voltage rail balancer circuit is provided, for use in a class D amplifier, adapted to sense an imbalance between a positive high voltage power supply and a negative high voltage power supply, the high voltage rail balancer circuit comprising: a first N-channel metal oxide semiconductor field effect transistor switch (first MOSFET switch) comprising a source terminal electrically connected to the positive high voltage power supply; a second N-channel metal oxide semiconductor field effect transistor switch (second MOSFET switch) comprising a source terminal electrically connected to the negative high voltage power supply; a first resistor-diode circuit; a second resistor-diode circuit; a three-winding transformer adapted to receive a substantially equal duty cycle switching signal and which is further adapted to simultaneously drive the first MOSFET switch to a conducting state and to drive the second MOSFET switch to a non-conducting state, and to simultaneously drive the second MOSFET switch to a conducting state and to drive the first MOSFET switch to a non-conducting state; and a rail-balancing over-current sense circuit electrically connected to both a source terminal of the first MOSFET switch and a drain terminal of the second MOSFET switch, wherein the rail-balancing over-current sense circuit is adapted to generate a voltage that is sensed by an over-current protection circuit to determine an over-voltage condition from either the positive high voltage power supply or the negative high voltage power supply.

According to the second aspect of the embodiments, the rail-balancing over-current sense circuit comprises: a series-connected inductor-resistor, wherein a first terminal of the inductor is electrically connected to both a source terminal of the first MOSFET switch and a drain terminal of the second MOSFET switch, and the second terminal of the inductor is connected to a first terminal of current-sensing resistor, and wherein a second terminal of the current-sensing resistor is electrically connected to circuit ground, and wherein the series-connected inductor-resistor is adapted to generate a voltage across the current sensing resistor that is sensed by the over-current protection circuit, to determine an over-current condition in the first or second MOSFET switch that is caused by over-voltage condition from either the positive high voltage power supply or the negative high voltage power supply.

According to the second aspect of the embodiments, the over-current protection circuit comprises: a negative over-current comparator with a first positive input and a first negative input; a positive over-current comparator with a second positive input and a second negative input; a negative voltage resistor divider network adapted to provide a negative voltage threshold to the first negative input of the negative over-current comparator; a positive voltage resistor divider network adapted to provide a positive voltage threshold to the first positive input of the positive over-current comparator, and wherein the voltage across the current sensing resistor of the series-connected inductor-resistor is received at the positive input of the positive over-current comparator and causes the positive over-current comparator to output an over-current protection signal that shuts down the high voltage rail balancer circuit when the received voltage is higher than the positive voltage threshold, and wherein the voltage across the current sensing resistor of the series-connected inductor-resistor is received at the negative input of the negative over-current comparator and causes the negative over-current comparator to output an over-current protection signal that shuts down the high voltage rail balancer circuit when the received voltage is lower than the negative voltage threshold.

According to a third aspect of the embodiments, a high voltage rail balancer circuit is provided, for use in a class D amplifier, and adapted to sense an imbalance between a positive high voltage power supply and a negative high voltage power supply, the high voltage rail balancer circuit comprising: a first N-channel metal oxide semiconductor field effect transistor switch (first MOSFET switch) comprising a source terminal electrically connected to the positive high voltage power supply; a second N-channel metal oxide semiconductor field effect transistor switch (second MOSFET switch) comprising a source terminal electrically connected to the negative high voltage power supply; a first cross-conduction prevention circuit; a second cross-conduction prevention circuit; a three-winding transformer adapted to receive a substantially equal duty cycle switching signal and which is further adapted to simultaneously drive the first MOSFET switch to a conducting state and to drive the second MOSFET switch to a non-conducting state, and to simultaneously drive the second MOSFET switch to a conducting state and to drive the first MOSFET switch to a non-conducting state, and wherein the first cross-conduction prevention circuit is adapted to change the first MOSFET switch from a conducting state to a non-conducting state faster than the second MOSFET switch can change from a non-conducting state to a conducting state, and the second cross-conduction prevention circuit is adapted to change the second MOSFET switch from a conducting state to a non-conducting state faster than the first MOSFET switch can change from a non-conducting state to a conducting state, such that cross conduction between the first and second MOSFET switches is substantially prevented.

According to the third aspect of the embodiments, the first cross-conduction prevention circuit comprises: a first resistor-diode circuit comprising a first Schottky diode with an anode terminal and a cathode terminal, and further wherein the anode of the first Schottky diode is electrically connected to a gate of the first MOSFET, and wherein the cathode of the first Schottky diode is electrically connected to a first drive output of the three winding transformer.

According to the third aspect of the embodiments, the second cross-conduction prevention circuit comprises: a second resistor-diode circuit comprising a second Schottky diode with an anode terminal and a cathode terminal, and further wherein the anode of the second Schottky diode is electrically connected to a gate of the second MOSFET, and wherein the cathode of the second Schottky diode is electrically connected to a second drive output of the three winding transformer.

According to a fourth aspects of the embodiments, a high voltage rail balancer circuit is provided, for use in a class D amplifier, adapted to sense an imbalance between a positive high voltage power supply and a negative high voltage power supply, the high voltage rail balancer circuit comprising: a first N-channel metal oxide semiconductor field effect transistor switch (first MOSFET switch) comprising a source terminal electrically connected to the positive high voltage power supply; a second N-channel metal oxide semiconductor field effect transistor switch (second MOSFET switch) comprising a source terminal electrically connected to the negative high voltage power supply; a first resistor-diode circuit; a second resistor-diode circuit; a three-winding transformer adapted to receive a substantially equal duty cycle switching signal and which is further adapted to simultaneously drive the first MOSFET switch to a conducting state and to drive the second MOSFET switch to a non-conducting state, and to simultaneously drive the second MOSFET switch to a conducting state and to drive the first MOSFET switch to a non-conducting state; and an over-current protection circuit.

According to a fifth aspect of the embodiments, a method for operating a high voltage rail balancer circuit is provided, the circuit being adapted to sense an imbalance between a positive high voltage power supply and a negative high voltage power supply, for use in a class D amplifier, the method comprising: driving, in a complementary manner, a first N-channel metal oxide semiconductor field effect transistor switch (first MOSFET switch) having a source terminal electrically connected to the positive high voltage power supply and a second N-channel metal oxide semiconductor field effect transistor switch (second MOSFET switch) having a source terminal electrically connected to the negative high voltage power supply by a three-winding transformer that receives a substantially equal duty cycle switching signal, wherein the first MOSFET switch is simultaneously driven to a conducting state while the second MOSFET switch is driven to a non-conducting state, and then the second MOSFET switch is simultaneously driven to a conducting state while the first MOSFET switch is driven to a non-conducting state; switching the first MOSFET switch by a first resistor-diode circuit from the conducting state to the non-conducting state faster than the second MOSFET switch changes from the non-conducting state to the conducting state; and switching the second MOSFET switch by a second resistor-diode circuit from the conducting state to the non-conducting state faster than the first MOSFET switch changes from the non-conducting state to the conducting state, such that cross conduction between the first and second MOSFET switches is substantially prevented.

### BRIEF DESCRIPTION OF THE DRAWINGS

The above and other objects and features of the embodiments will become apparent and more readily appreciated from the following description of the embodiments with reference to the following figures. Different aspects of the embodiments are illustrated in reference figures of the drawings. It is intended that the embodiments and figures disclosed herein are to be considered to be illustrative rather than limiting. The components in the drawings are not necessarily drawn to scale, emphasis instead being placed upon clearly illustrating the principles of the aspects of the embodiments. In the drawings, like reference numerals designate corresponding parts throughout the several views.

FIG. 1 illustrates a block diagram of a half-bridge rail balancing circuit according to aspects of the embodiments.

FIG. 2 illustrates a schematic diagram of a three winding gate driver transformer rail balancing (rail balancer) circuit used in the half-bridge rail balancing circuit shown in FIG. 1 according to aspects of the embodiments.

FIG. 3 illustrates a schematic diagram of an over-current protection circuit used in the half-bridge rail balancing circuit shown in FIG. 1 according to aspects of the embodiments.

FIG. 4 illustrates a schematic diagram of a rail balancer enable/disable circuit used in the half-bridge rail balancing circuit shown in FIG. 1 according to aspects of the embodiments.

FIG. 5A illustrates a voltage waveform at a switching node V_{SN}, which is the circuit point where inductor L6 connects to a drain of lower metal oxide semi-conductor field effect transistor (MOSFET) Q60 and a source of upper MOSFET Q61 in the rail balancer circuit of the half-bridge rail balancing circuit shown in FIG. 1, and wherein a positive rail power supply is greater in absolute magnitude than a negative rail power supply, according to aspects of the embodiments.

FIG. 5B illustrates the direction of current flow from switching node V_{SN} through inductor L6 and current sense resistor R1044, as shown in FIG. 1, when the conditions of FIG. 5A exist in the half-bridge rail balancing circuit shown in FIG. 1 according to aspects of the embodiments.

FIG. 6A illustrates a voltage waveform 600 at a switching node V_{SN}, which is the circuit point where inductor L6 connects to a drain of lower MOSFET Q60 and a source of upper MOSFET Q61 in rail balancing circuit of the half-bridge rail balancing circuit 100 as shown in FIG. 1, and wherein a negative rail power supply is greater in absolute magnitude than a positive rail power supply, according to aspects of the embodiments.

FIG. 6B illustrates the direction of current flow from switching node V_{SN} through inductor L6 and current sense resistor R1044, as shown in FIG. 1, when the conditions of FIG. 6A exist in the half-bridge rail balancing circuit shown in FIG. 1 according to aspects of the embodiments.

FIG. 7 illustrates a voltage waveform 700 at a switching node V_{SN}, which is the circuit point where inductor L6 connects to a drain of lower MOSFET Q60 and a source of upper MOSFET Q61 in the rail balancer circuit of the half-bridge rail balancing circuit shown in FIG. 1, and wherein the rail balancer circuit is in an idle state, meaning that no net DC current is being drawn from either the positive rail power supply or the negative rail power supply, and both MOSFETs Q60 and Q61 are switching at about 50% duty cycle, and both positive and negative rails have equal voltage magnitude (i.e. are balanced).

FIG. 8 illustrates a series of calculations regarding an approximation for power supply pumping using a conventional Class-D Amplifier using a half-bridge power stage.

FIG. 9 illustrates a flowchart of a method for operating the half-bridge rail balancing circuit of FIG. 1 according to aspects of the embodiments.

FIG. 10 illustrates a simplified diagram of a half-bridge Class-D power stage amplifier using bipolar “split” power supply rails used in a Class-D Amplifier according to aspects of the embodiments.

FIG. 11 illustrates a current waveform formed through an output inductor L1 of the Class-D power stage amplifier shown in FIG. 10 when the Class-D amplifier is at idle—that is, when the input signal is a fifty percent duty cycle signal—according to aspects of the embodiments.

FIG. 12 illustrates a current waveform formed through the inductor L1 of the Class-D power stage amplifier shown in FIG. 10 when the Class-D amplifier experiences an eighty percent duty cycle input signal according to aspects of the embodiments.

FIG. 13 illustrates a current waveform formed through a bottom switch of the half-bridge Class-D power stage amplifier as shown in FIG. 10 when the Class-D amplifier experiences an eighty percent duty cycle input signal according to aspects of the embodiments.

FIG. 14 illustrates the current waveform of FIG. 13 flowing through a bulk capacitor on a negative power supply rail of the Class-D amplifier according to aspects of the embodiments.

FIG. 15 is a simplified diagram of the half-bridge rail balancing circuit of FIGS. 1 and 2 according to aspects of the embodiments.

FIG. 16 illustrates the half-bridge rail balancing circuit of FIG. 15 when there is an imbalance in the power rail voltages, i.e., an absolute magnitude of the negative power rail voltage is larger than that of the positive power rail voltage according to aspects of the embodiments.

FIG. 17 illustrates a DC balancing current formed through an output inductor L6 of the half-bridge rail balancing circuit shown in FIG. 15 when the negative power supply rail is greater in magnitude then the positive power supply rail according to aspects of the embodiments.

FIG. 18 illustrates the current waveform of FIG. 17 flowing through the bulk capacitor on the negative power supply rail of the Class-D amplifier according to aspects of the embodiments.

FIG. 19 illustrates a current waveform flowing through the bulk capacitor on the positive power supply rail of the Class-D amplifier according to aspects of the embodiments.

### DETAILED DESCRIPTION

The embodiments are described more fully hereinafter with reference to the accompanying drawings, in which embodiments of the inventive concept are shown. In the drawings, the size and relative sizes of layers and regions may be exaggerated for clarity. Like numbers refer to like elements throughout. The embodiments may, however, be embodied in many different forms and should not be construed as limited to the embodiments set forth herein. Rather, these embodiments are provided so that this disclosure will be thorough and complete, and will fully convey the scope of the inventive concept to those skilled in the art. The scope of the embodiments is therefore defined by the appended claims. The detailed description that follows is written from the point of view of a control systems company, so it is to be understood that generally the concepts discussed herein are applicable to various subsystems and not limited to only a particular controlled device or class of devices, such as media presentation products, which include audio Class-D amplifiers.

Reference throughout the specification to “one embodiment” or “an embodiment” means that a particular feature, structure, or characteristic described in connection with an embodiment is included in at least one embodiment of the embodiments. Thus, the appearance of the phrases “in one embodiment” or “in an embodiment” in various places throughout the specification is not necessarily referring to the same embodiment. Further, the particular feature, structures, or characteristics may be combined in any suitable manner in one or more embodiments.

### LIST OF REFERENCE NUMBERS FOR THE ELEMENTS IN THE DRAWINGS IN NUMERICAL ORDER

The following is a list of the major elements in the drawings in numerical order.
100 Half-Bridge Rail Balancing Circuit (HBRBC)
102 Three Winding Transformer Driver Half-Bridge Rail Balancer (Rail Balancer) Circuit
104 Over-Current Protection Circuit
106 Rail Balancer Enable/Disable Circuit
202 Rail Balancer Over-Current Sense Circuit
204 Cross-Conduction Prevention Circuit
500 Waveform at Switching Node V_{SN} In Rail Balancer Circuit 102 When the Magnitude of V_{POS} is Greater Than the Magnitude of V_{NEG}
600 Waveform at Switching Node V_{SN}, In Rail Balancer Circuit 102 When the Magnitude of V_{NEG} is Greater Than the Magnitude of V_{POS}
700 Waveform at Switching Node V_{SN}, In Rail Balancer Circuit 102 When the Rail Balancing Circuit is Idle (i.e. the voltage magnitude of the positive and negative rails is equal and therefore balanced)
900 Method for Operating Half Bridge Rail Balancing Circuit
902-910 Method Steps of Method 900
1000 Half-Bridge Class-D Power Stage Amplifier
1002 Top Switch S_{T} in Half-Bridge Class-D Power Stage Amplifier 1000 (Top Switch S_{T})
1004 Bottom Switch S_{B} in Half-Bridge Class-D Power Stage Amplifier 1000 (Bottom Switch S_{B})
1006 Series Inductor L used in Half-Bridge Class-D Power Stage Amplifier 1000 (Series Inductor L1)
1008 Shunt Capacitor used in Half-Bridge Class-D Power Stage Amplifier 1000 (Shunt Capacitor)
1010 Shunt Load Resistance R_{LOAD} (Shunt Load R_{LOAD})
1100 Current Waveform through Series Inductor L1 1006 at 50% Duty Cycle
1200 Current Waveform through Series Inductor L1 1006 at 80% Duty Cycle
1300 Current Waveform formed through Bottom Switch S_{B} 1004 of Half Bridge Class-D Power Stage Amplifier 1000 at 80% Duty Cycle
1402 Negative Power Supply Rail Bulk Capacitor (NPSR Bulk Capacitor)
1500 Half-Bridge Rail Balancer Circuit (Rail Balancer Circuit)
1502 Half-Bridge Rail Balancer Circuit Top Transistor Switch (Top Switch S_{T})
1504 Half-Bridge Rail Balancer Circuit Bottom Transistor Switch (Bottom Switch S_{B})
1506 Half-Bridge Rail Balancer Circuit Inductor (HBRBC Inductor)
1700 DC Balancing Current When the Negative Power Supply Rail is Greater in Magnitude Than the Positive Power Supply Rail
1802 Half-Bridge Rail Balancer Circuit Negative Power Rail Bulk Capacitor (−Bulk Capacitor)
1902 Half-Bridge Rail Balancer Circuit Positive Power Rail Bulk Capacitor (+Bulk Capacitor)
1904 DC Balancing Current When the Positive Power Supply Rail is Greater in Magnitude Than the Negative Power Supply Rail

### LIST OF ACRONYMS USED IN THE SPECIFICATION IN ALPHABETICAL ORDER

The following is a list of the acronyms used in the specification in alphabetical order.
C Capacitor
D Diode
DC Direct Current
DSC Drive Signal Circuit
HBRBC Half Bridge Rail Balancing Circuit
HSVCC High Speed Voltage Comparator Circuit
MOSFET Metal Oxide Semiconductor Field Effect Transistor
OCP Over-Current Protection
Q Transistor
R Resistor
Tn Transformer [number “n” ]
V Volt(s)
W Watt(s)

### LIST OF VALUES OF SEVERAL OF THE COMPONENTS ACCORDING TO ASPECTS OF THE EMBODIMENTS

The following is a list of values for several of the discrete components shown in the drawings.

| Ref-Des. | Description |
|---|---|
| T4 | PO544NL Transformer |
| U3 | LM5033 |
| U4 | LTC6702 Dual Comparators |
| D68, D70 | 1N5819 Schottky Diodes |
| D69 | BAT54C Schottky Diodes |
| Q59A, B | NTZD3154N MOSFETs |
| Q60, Q61 | BSC160N MOSFETs |
| Z5 | 4687 Zener Diode |

The different aspects of the embodiments described herein pertain to the context of an audio amplifier circuit, but is not limited thereto, except as may be set forth expressly in the appended claims.

For 40 years Crestron Electronics Inc., has been the world's leading manufacturer of advanced control and automation systems, innovating technology to simplify and enhance modern lifestyles and businesses. Crestron designs, manufactures, and offers for sale, integrated solutions to control audio, video, computer, and environmental systems. In addition, the devices and systems offered by Crestron streamlines technology, improving the quality of life in commercial buildings, universities, hotels, hospitals, and homes, among other locations. Accordingly, the systems, methods, and modes of the aspects of the embodiments described herein, as embodied as half-bridge rail balancing circuit (HBRBC) 100 can be manufactured by Crestron Electronics Inc., located in Rockleigh, NJ.

Aspects of the embodiments are described herein in the context of a 200 watt (W) Class-D audio amplifier, but is not limited thereto, except as may be set forth expressly in the appended claims. For example, while a 200 W Class-D audio amplifier is used as an example of an implementation of the embodiments, those of skill in the art can readily appreciate that the specified power rating can be something other than 200 W, e.g., 100 W, 500 W, among virtually limitless other power ratings. Thus, the embodiments can be easily “scaled” by those skilled in the art to suit it for lower or higher power amplifiers at optimal price-points for those different power levels.

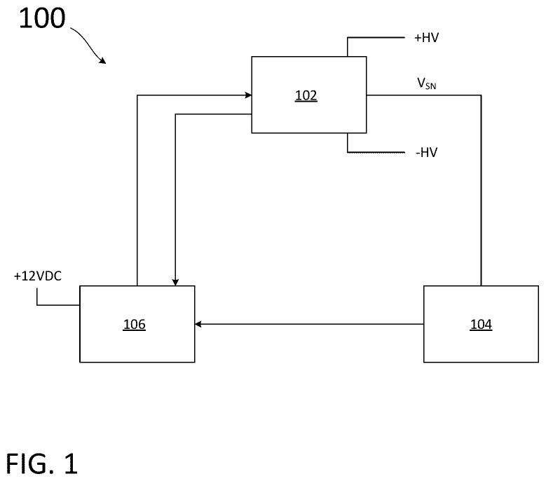

Half-bridge rail balancing circuit (HBRBC) 100, as shown in FIG. 1, comprises three winding transformer driver half-bridge rail balancer (rail balancer circuit) 102, over-current protection circuit 104, and rail balancer enable/disable circuit 106 (which includes 50% duty cycle driver controller circuit U3) according to aspects of the embodiments.

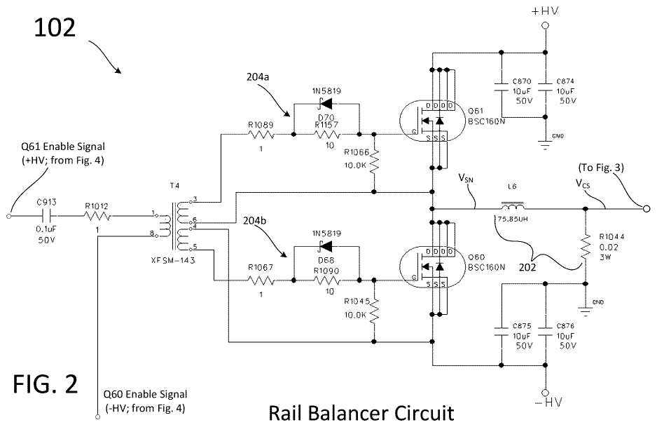

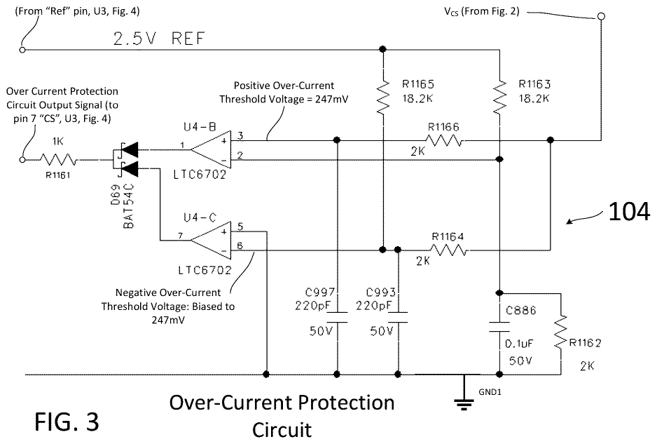

Each of the circuits of FIGS. 2, 3, and 4 will now be described in greater detail.

FIG. 2 illustrates a schematic diagram of rail balancer circuit 102 used in HBRBC 100 shown in FIG. 1 according to aspects of the embodiments.

The main components of rail balancer circuit 102, as shown in FIG. 2, comprise N-channel metal oxide semiconductor field effect transistor (MOSFET) switches Q60 and Q61, fast acting diodes D68, D70, three winding transformer T4, output inductor L6, and current sensing resistor R1044 according to aspects of the embodiments. Inductor L6 and current sensing resistor R1044 can together be described as rail balancer over-current sense circuit 202 according to aspects of the embodiments.

Rail balancer circuit 102 comprises two N-channel metal oxide semiconductor field effect transistors (MOSFETs) Q60 and Q61 that are switched at a fixed 50% duty cycle. This means that the on-time for each of MOSFETs Q60, Q61 is equal or substantially equal. MOSFETs Q60, Q61 drive inductor L6, whose far terminal is connected to ground through current-sensing resistor R1044. As those of skill in the art can appreciate, a voltage applied across an inductor (V_{L}) will induce a change in the current through the inductor (di), proportional to the time duration during which the voltage is applied (dt), and inversely proportional to the inductance value (L). This is reflected in Equation (01), shown below:

$$( {V}_{L} ) = L \frac{{d}_{i}}{{d}_{t}} \qquad Eq . ( 01 )$$

Furthermore, the direction of the current change through the inductor will depend on the polarity of the voltage applied (V_{L}). In rail balancer circuit 102, the positive rail voltage is applied across inductor L6 when Q61 is on, and the negative rail voltage is applied when Q60 is on. According to aspects of the embodiments, if the magnitude of the positive rail voltage (V_{POS}) is equal to the magnitude of the negative rail voltage (V_{NEG}), and the time duration that they are applied is equal (50% duty cycle), then the ramping-up of current in the inductor (di), when the upper MOSFETs Q61 is on will be exactly equal to the ramping down of current (di) in the inductor, when the lower MOSFETs Q60 is on. The average (DC) value of inductor L6 current will therefore be OA. Inductor L6 current will ramp positive when Q61 is on, but then will ramp negative an equal amount when Q60 is on, such that the average value of OA will not change. If however, the positive rail voltage magnitude is greater than the negative rail voltage magnitude, then di for the positive current ramp up will exceed di for the ramp down current, and there will be a net positive current flowing from the positive rail, through inductor L6, into ground (through the current-sensing resistor). The current through inductor L6 (balancing current) will continue to increase each time Q61 switches on, for as long as the positive rail voltage magnitude is greater than the negative rail voltage magnitude. This balancing current flows in a direction that will discharge capacitors C870, 874 attached to the higher voltage rail, and in this way, an auto-balancing function is realized by the rail balancer circuit according to aspects of the embodiments. The above description explains the circuit operation for the situation where the positive rail voltage magnitude exceeds the value of the negative rail voltage magnitude. However, it will be understood by those skilled in the art that the behavior is reciprocal and will occur in a reciprocal fashion if the magnitude of the negative rail voltage exceeds the magnitude of the positive rail voltage.

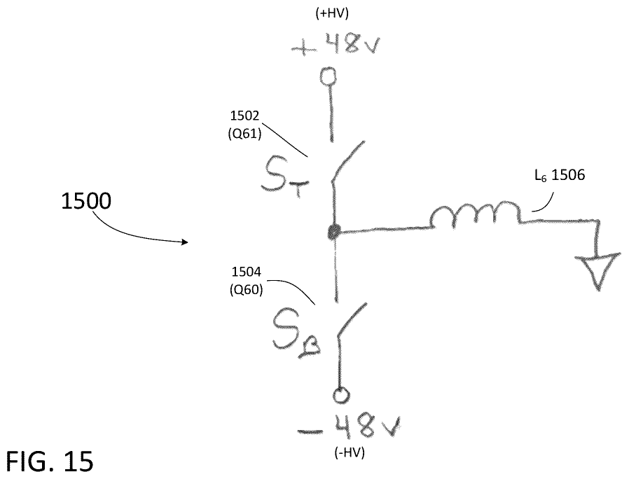

Thus, according to aspects of the embodiments, rail balancing circuit 102 will induce a rail-voltage-balancing action. The rail voltage balancing action according to aspects of the embodiments is described in greater detail below in regard to FIGS. 15-18.

FIG. 3 illustrates a schematic diagram of an over-current protection (OCP) circuit 104 used in the HBRBC 100 shown in FIG. 1 according to aspects of the embodiments.

OCP circuit 104 provides over-current protection for MOSFETs Q60 and Q61 in rail balancer circuit 102. As described above, when the positive and negative voltage rails are equal in voltage magnitude, there will be an AC ramping current in inductor L6 (symmetrical around OA), and the DC current will be OA. However, when the rail voltage magnitudes are unbalanced (i.e., the positive high voltage rail is greater in magnitude than the negative high voltage rail, or visa-versa), there will be a net DC current flowing in inductor L6 and R1044, and the peak AC current will rise. The peak AC current level will be sensed by current-sensing resistor R1044, and develop a voltage across it V_{CS}.

Comparator U4 is configured as a window comparator, with 2 voltage thresholds. The positive over-current threshold voltage is set by resistor divider R1163 and R1162, to +247.5 mV=(2.5 v×2000/(2000+18,200)).

The negative over-current threshold is set as follows: The negative input pin of over-current comparator U4-C (pin 5) is connected to ground (0V). Resistor divider R1164 and R1165 provide a positive bias voltage to pin 6 of U4-C—2.5 v×2000/(2000+18,200)=247.5 mV (note that one end of R1164 is connected to one end of R1044, shown in FIG. 2, as V_{CS}; because R1044 is only 0.020, it can be neglected in this calculation, and essentially provides a short to ground for the purposes of determining the resistor divider network). In order for pin 6 to be pulled below the switching threshold voltage (GND), then the voltage across R1104, V_{CS}, must be driven more negative than −247.5 mV. As those of skill in the art can appreciate, it is generally unworkable, and undesirable, to drive an input of an integrated circuit (IC) negative when there is no negative supply available to the IC. However, in this case, U4-C pin 6 can tolerate a small negative voltage at its input. U4-C pin 6 only needs to be driven microvolts below ground in order for the U4-C pin 7 output to switch high. According to aspects of the embodiments, this uniquely designed circuit allows the use of the negative V_{CS} to create a small negative input that is less than the specified amount that can be tolerated at the input of U4 so that a negative overcurrent condition can be detected.

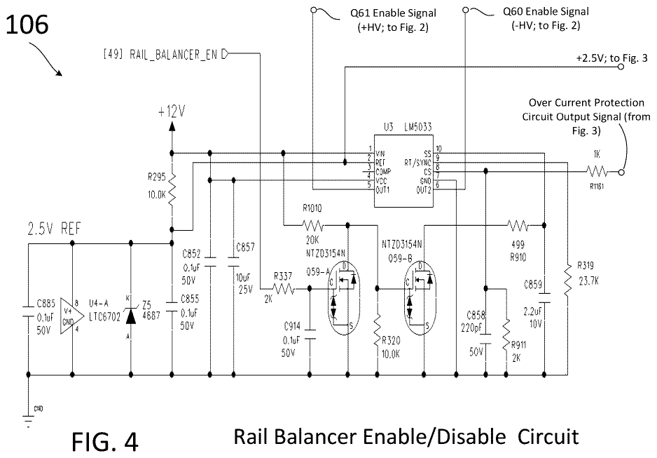

According to aspects of the embodiments, when either of these positive or negative over-current thresholds are reached, the output of comparators U4-B or U4-C will switch positive (to +2.5V), and drive the CS pin of U3 to approximately 1.25V (through Schottky diodes D69 and resistor divider R1161 and R911). The shutdown threshold for the CS pin is 0.5V. When CS is driven above 0.5V, the switching output drive from U3 will cease (discussed in greater detail below in regard to FIG. 4, and rail balance enable/disable circuit 106). The soft start capacitor C859 will be discharged, and a restart of U3 will commence with duty cycle ramping up from minimum to maximum (50% duty cycle). In this way, the MOSFETs Q60 and Q61 are protected from damage due to excessive current.

FIG. 4 illustrates a schematic diagram of rail balancer enable/disable (RBED) circuit 106 used in HBRBC 100 shown in FIG. 1 according to aspects of the embodiments.

The main components of RBED circuit 106 comprise controller circuit U3, soft start capacitor C859, and transistor pair Q59A, 59B, along with several ancillary components that provide filtering functions and proper voltage levels for the power needs of circuit U3.

RBED circuit 106 is responsible for timing and control of rail balancer circuit 102 according to aspects of the embodiments. IC U3 has two push-pull (totem-pole) outputs, (pins 5 and 6) which drive small gate-drive transformer T4 (shown in FIG. 2) with 50% duty-cycle switching. The duty cycle of U3 is controlled by the voltage on the COMP pin (pin 3). When the COMP pin is greater than 3.5V, the duty-cycle is fixed at maximum (50%). There is an internal resistive pullup on the COMP pin, to +5.2V, so that the duty-cycle will be fixed at maximum of 50%. The value of the resistor on pin 9 sets the switching frequency. With R319=23.7 Kohm, the switching frequency of each output pin (5 and 6) will be approximately 100 KHz (providing a period of 10 μsec, and an “on” or high voltage time of 5 μsec and an “off” or low voltage time of 5 μsec). The primary winding of gate-drive transformer T4 will be driven symmetrically, and the two independent secondary windings will likewise have symmetrical drive waveforms, which will switch the corresponding MOSFETs Q60, Q61 ON/OFF. Diodes D68 and D70 (shown in FIG. 2) serve to speed up the switch-off time of the MOSFETs relative to the switch-on time. This eliminates the possibility of cross-conduction, which could occur, if both MOSFETs were to be driven ON at the same time. Diode D70 and R1157 can be referred to as cross-conduction prevention circuit 204a, and diode D68 and R1090 can be referred to as cross-conduction prevention circuit 204b.

U3 also has an internal 2.5V reference voltage source at pin 2, which is used to power over-current protection comparator U4 (shown in FIG. 3). In addition, dual MOSFETs Q59 provide enable control for U3. U3 can be disabled by pulling the “RAIL_BALANCER_EN” signal low, and this causes the soft-start pin of U3 (pin 10) to be pulled low through resistor R910, and switching of U3 output pins (5 and 6) and the half-bridge power stage will stop. When “RAIL_BALANCER_EN” signal is high—its normal condition, Q59-A is on, causing a virtual short to ground through R1010, and the gate of Q59-B is forced low, turning off Q59-B, allowing soft-start capacitor C859 to charge up. When “RAIL_BALANCER_EN” signal goes low, however, Q59-A is now turned off, and the input to the of Q59-B is now high, turning on Q59-B, and it appears as a virtual short to resistor R910, driving pin SS to ground, and causing capacitor C859 to discharge through R910 and the drain-to-source path of MOSFET Q59-B, according to aspects of the embodiments.

Attention is directed towards rail balancer circuit 102 as shown in FIG. 2. As those of skill in the art can appreciate, however, while transistors Q60, Q61, Q59-A, and Q59-B have been described as MOSFET transistors, other types of transistor technology can be used in implementing HBRBC 100, which may necessitate different values of certain components, but which do not substantively change the theory of operation of HBRBC 100 according to aspects of the embodiments.

Q60 and Q61 are N-channel MOSFET switches arranged in a half-bridge topology. They are driven at a substantially fixed and precise duty cycle of about 50% by Controller IC U3 (FIG. 4). Since the circuit runs at a duty-cycle of a about 50%, a simple gate-drive transformer (3-winding) is used to drive the gates of MOSFETs Q60 and Q61. As discussed above, HBRBC 100 uses a simple, single winding power inductor L6. Current sensing (CS) resistor 1044 (R1044) is a current sensing resistor that interfaces with, and is therefore part of, over-current protection circuit 104, which prevents HBRBC 100 from being damaged due to an over-current condition.

Attention is directed towards FIG. 3, and in particular to over-current protection circuit 104. According to aspects of the embodiments, current flowing through inductor L6 also flows through current sense resistor R1044 (CS resistor R1044), creating a voltage V_{CS} that is sensed by first and second comparators U4B and U4C. As those of skill in the art can appreciate, very little current flows into (or from) the high impedance inputs of first and second comparators U4B and U4C, thereby minimizing any errors in the voltage drop across CS R1044. Two comparators are used in over-current protection circuit 104 as the current through R1044 can flow in two different directions depending on the direction of balancing current flowing through L6. If balancing current needs to flow from V_{POS} to V_{NEG}, then the current through L6 and CS R1044 will be in a direction that generates a positive voltage across R1044 (relative to ground potential=0V). Likewise, if balancing current needs to flow from V_{NEG} to V_{POS} then a current will flow in L6 and CS R1044 in a direction that will generate a negative voltage with respect to ground. For this reason, first comparator U4B is arranged to detect a positive peak voltage across CS R1044 (representing a positive peak current), and second comparator U4C is arranged to detect a negative peak voltage across CS R1044 (representing a negative peak current). When either the positive peak voltage or negative peak voltage sensed across CS R1044 exceeds a threshold value, then the outputs of first and second comparators U4B and U4C (respectively) will switch to a logic level high and drive the current sense (CS) pin of drive controller U3 high, which will cause both outputs of drive controller U3 to switch off, which will serve to reduce the current level in L6 and CS R1044, and will therefore protect the MOSFETs Q60 and Q61 against damage due to an overcurrent condition.

Dual MOSFETs Q59, which are part of RBED circuit 106, is driven by an enable signal according to aspects of the embodiments. Q59A-B and associated circuitry (R337, R1010, R320, R910, C914) are optional, and allow HBRBC 100 to be disabled or enabled as needed. By way of non-limiting example, Q59 and associated circuitry can be used to disable the balancer if a very low power standby state is desired.

According to aspects of the embodiments, because HBRBC 100 runs at a substantially fixed frequency and a substantially fixed duty cycle of about 50%, the drive of MOSFETs Q60 Q61 is substantially simplified. A simple, small 3-winding gate-drive transformer T4 is employed as the drive to MOSFETs Q60 and Q61. The primary winding drive is AC-coupled through capacitor C913, and the two secondary windings have simple speed-up diodes D68, D70 to speed MOSFET turn-off, relative to turn-on. This has the effect of introducing a small deadtime into the switching timing of the MOSFETs Q60 and Q61, substantially preventing cross conduction, which would occur if both MOSFETs Q60 and Q61 were to be switched on at the same time. As those of skill in the art can appreciate, cross conduction between MOSFETs Q60 and Q61 occurs when both are turned on at the same time, and the two transistors present a short circuit from the positive supply rail to the negative supply rail. This short circuit causes extremely high current to flow, and causes both MOSFETs Q60 and Q61 to fail very quickly.

According to aspects of the embodiments, the adjustment of MOSFETs Q60 and Q61 switch timing and deadtime is precisely controlled, as this is a non-ideality and contributes to errors in voltage balancing. Other circuit parameters that contribute to non-ideality are the on-resistance of the MOSFETs switches (R_{DS-ON} of Q60 and Q61) as well as the body-diode forward voltage (V_{F}) of these same MOSFETs.

Non-Idealities & Error Sources that can Impair Voltage Balancing

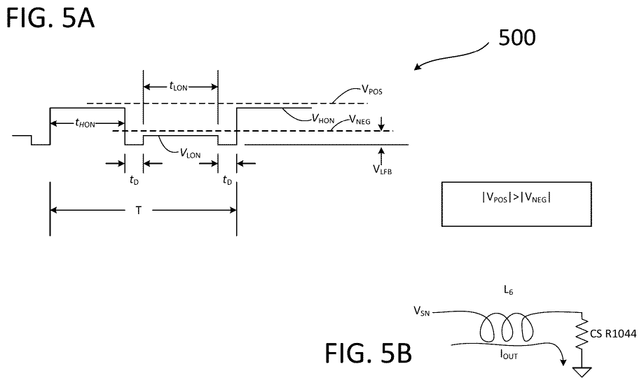

Attention is now directed to FIGS. 5A and 5B. FIG. 5A illustrates a voltage waveform 500 at the switching node V_{SN}, which is at the intersection of inductor L6 and the source of Q61 and drain of Q60 in rail balancer circuit 102. FIG. 5B illustrates the direction of current flow in regard to the switching node V_{SN} and inductor L6, as shown in FIG. 1. FIG. 5A is drawn in a manner such that the waveform imperfections (error sources) are exaggerated for clarity. It illustrates that the switching node waveform is not a perfect 50% duty cycle square wave at the switching frequency, which would imply spending exactly half the time at the positive rail, and exactly half the time at the negative rail. Instead, nonidealities have been taken into account in regard to the voltage waveform of FIG. 5A. The voltage waveform of FIG. 5A illustrates the condition in which the two supply rails are out-of-balance, and the positive supply rail is greater (in absolute value) than the negative supply rail. That is,

|V_{POS}|>|V_{NEG}|

In this case, the balancer will act to draw balancing current from the positive rail, and “pump” this current into the negative rail. This will reduce the voltage of the (higher) positive rail. It must be appreciated that the action of the balancer is in opposition to the action of the Class-D amplifier, which is attached to these same power rails, and is CAUSING the supply pumping overvoltage issues.

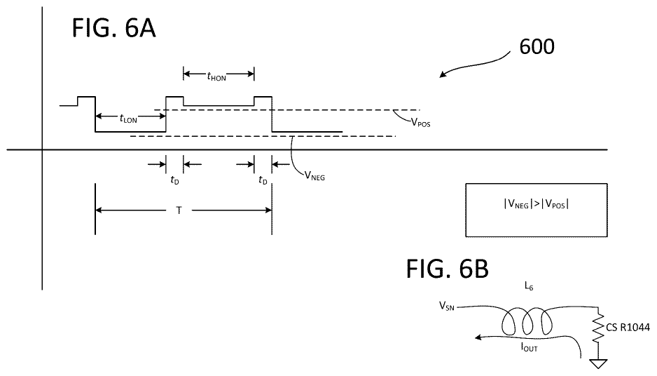

FIG. 6A illustrates a voltage waveform 600 at a switching node V_{SN}, which is the circuit point where inductor L6 connects to a drain of lower MOSFET Q60 and a source of upper MOSFET Q61 in rail balancing circuit of the half-bridge rail balancing circuit 100 as shown in FIG. 1, and wherein a negative rail power supply is greater in absolute magnitude than a positive rail power supply, according to aspects of the embodiments.

FIG. 6B illustrates the direction of current flow from switching node V_{SN} through inductor L6 and current sense resistor R1044, as shown in FIG. 1, when the conditions of FIG. 6A exist in the half-bridge rail balancing circuit shown in FIG. 1 according to aspects of the embodiments.

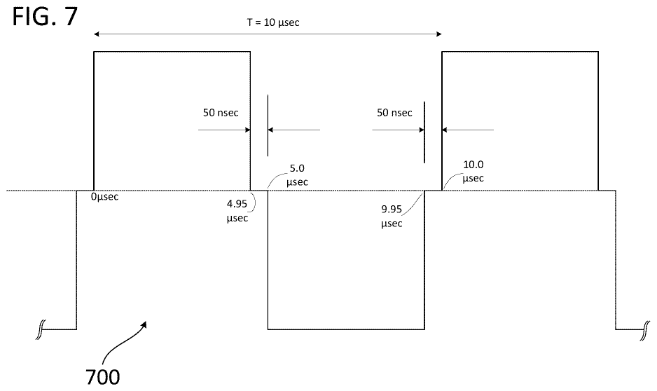

FIG. 7 illustrates a voltage waveform 700 at a switching node V_{SN}, which is the circuit point where inductor L6 connects to a drain of lower MOSFET Q60 and a source of upper MOSFET Q61 in the rail balancer circuit of the half-bridge rail balancing circuit shown in FIG. 1, and wherein the rail balancer circuit is an idle state, meaning that no DC current is being drawn from either the positive rail power supply or the negative rail power supply, and both MOSFETs Q60 and Q61 are switching at 50% duty cycle, according to aspects of the embodiments. This will occur when the magnitude of the positive and negative rail voltages are equal. Shown below are a series of calculations that illustrate the function and effectiveness of rail balancer 102 according to aspects of the embodiments. The condition analyzed is one in which a low frequency audio signal (20 Hz for example) is causing the positive power supply, VPOS, to increase in voltage. As those of skill in the art can appreciate, this condition can occur when there is a negative voltage audio output signal from the Class-D amplifier. As previously stated, a Class-D amplifier employing a half-bridge topology with positive and negative power supply rails will cause supply rail pumping. The method in which this occurs will be explained later in this document. Several assumptions will be made in order to perform the calculations (illustrated in Equations (02)-(04) for rail balancer 102 according to aspects of the embodiments (although a simplified circuit diagram of rail balancer 102 is shown in FIG. 15, as rail balancer circuit 1500, reference shall be made in regard to this discussion to only rail balancer 102 in fulfillment of the dual purposes of clarity and brevity). In a non-limiting example, a peak balancing current of 10 A will be assumed, along with rail voltages of VPOS=100V and VNEG=−100V nominal.

FIG. 5A is used to illustrate the operation of rail balancer 102 according to aspects of the embodiments. The idealized waveform is what would be observed for the condition where the |positive rail| voltage is pumped up greater than the |negative rail| voltage. NOTE that absolute value bars bracket the rail voltages to avoid polarity confusion. In this condition, current must be sourced from the positive rail capacitor, to reduce the overvoltage of the positive rail, and this current must be pumped into the rail capacitors of the negative rail. The waveform exaggerates the effects of the error sources to make them more visible and aid in understanding their effects.

The Equations are simplified by understanding that the positive “voltage×time product” (VT_{P}), across the balancing inductor L6, must equal the negative “voltage×time product” (VT_{N}). The following variables used in Equations (02)-(04) are defined as follows:
I_{BAL}=The balancing current amplitude (in Amps)
t_{D}=deadtime (an adjustable parameter)
R_{DSON}=MOSFET on-state resistance (depends on MOSFET selection)
V_{F}=MOSFET body diode forward voltage from source-to-drain (depends on MOSFET selection)
t_{HON}=t_{LON}=t_{ON}=(T−2t_{D})/2
V_{POS} and V_{NEG}=The positive and negative rail voltages, respectively
V_{HON}=V_{POS}−(I_{BAL})(R_{DSON})
V_{LON}=|V_{NEG}|+(I_{BAL})(R_{DSON})
V_{LFB}=|V_{NEG}|+V_{F}

For the waveform in FIG. 5A, the positive voltage×time product (VT_{P}) is:

VT_{P}=V_{HON}t_{ON} Eq. (02)

And the negative voltage×time product (VT_{N}) is:

VT_{N}=V_{LON}t_{ON}+V_{LPB}2t_{D} Eq.(03)

Next, the positive voltage×time product is set equal to the negative voltage×time product (Eq. (02)=Eq. (03)). The values of all variables above are entered, and the value of the nominal (un-pumped) regulated negative rail voltage is entered. The equality is then solved for the resulting value of the worst-case pumped-up voltage of the positive rail. To illustrate the effect of all sources of error for this half-bridge balancer, Table 01 below lists the resulting values of the pumped up positive rail (V_{POS}) based on the variable values listed in the table, and calculated using this expression for V_{POS-PUMPED}:

$${V}_{POS - PUMPED} = ( {V}_{LON} \times {t}_{ON} ) + \frac{{V}_{LFB} \times 2 {t}_{d}}{{t}_{ON}} + ( {I}_{BAL} \times {R}_{DSON} ) \qquad Eq . ( 04 )$$

TABLE 01

| FREQ/ | | | | | | |
|---|---|---|---|---|---|---|
| tON | t_{D} | R_{DSON} | V_{F} | I_{BAL} | V_{NEG} | V_{POS-PUMPED} |
| 100 KHz/ | 50 | 25 mΩ | 1V | 10A | 100 V | 102.54 V |
| 4.95 usec | nsec | | | | | |
| 100 KHz/ | 50 | 50 mΩ | 1V | 10A | 100 V | 103.04 V |
| 4.95 usec | nsec | | | | | |
| 100 KHz/ | 25 | 25 mΩ | 1V | 10A | 100 V | 101.52 V |
| 4.975 usec | nsec | | | | | |
| 100 KHz/ | 25 | 50 mΩ | 1V | 10A | 100 V | 102.02 V |
| 4.975 usec | nsec | | | | | |
| 200 KHz/ | 50 | 25 mΩ | 1V | 10A | 100 V | 104.62 V |
| 2.45 usec | nsec | | | | | |
| 200 KHz/ | 50 | 50 mΩ | 1V | 10A | 100 V | 105.12 V |
| 2.45 usec | nsec | | | | | |
| 200 KHz/ | 25 | 25 mΩ | 1V | 10A | 100 V | 102.54 V |
| 2.475 usec | nsec | | | | | |
| 200 KHz/ | 25 | 50 mΩ | 1V | 10A | 100 V | 103.04 V |
| 2.475 usec | nsec | | | | | |

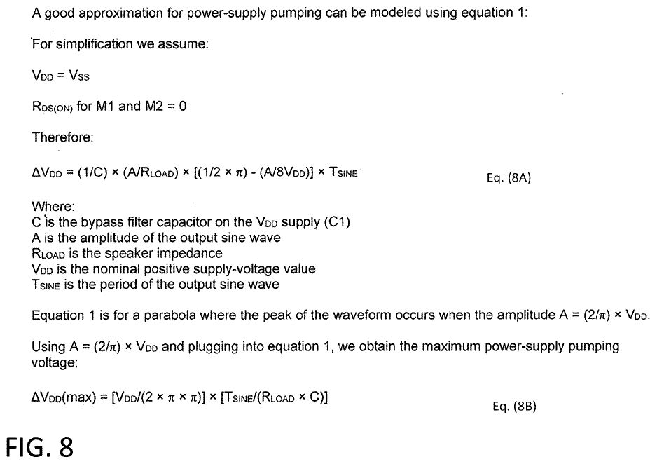

These results illustrate the effectiveness of rail balancer 102 according to aspects of the embodiments. The worst-case voltage increase caused by pumping is only 5.12V for rail balancer 102 according to aspects of the embodiments, as compared to a voltage increase of 39.76V without rail balancer 102 (per the Equations in FIG. 8), which are discussed in greater detail below. Also, the voltage increase using rail balancer 102 according to aspects of the embodiments is relatively unaffected by the value of rail capacitance and audio frequency, whereas when rail balancer 102 according to aspects of the embodiments is not used, the degree of rail pumping and rail voltage increase is heavily dependent on the value of rail capacitance and audio frequency.

Those of skill in the art can now appreciate that when using rail balancer 102 according to aspects of the embodiments the positive voltage supply will change by only 5.12% when a maximum current draw of about 10 amps occurs from the negative supply rail. As stated before, the operation is exactly reciprocal, such that the negative voltage supply will change by only 5.12% when a maximum current draw of about 10 amps occurs from the positive supply rail.

The calculations shown above in Table 01 illustrate a maximum power supply voltage deviation in a first power supply when a maximum current draw of about 10 amps occurs in a second power supply of opposite polarity to the first power supply, wherein a first set of timing, circuit, and power supply parameters are incorporated, according to aspects of the embodiments.

The non-limiting example calculations shown above illustrate the dependency of the peak deviation of the supply rails to variations in the following parameters, according to aspects of the embodiments. According to aspects of the embodiments, “pumping voltage deviation” is the deviation in the nominal value of a power supply due to some external factor.
Deadtime: Pumping voltage deviation INCREASES with increasing deadtime
R_{DS(on)} of the MOSFETs: Pumping voltage deviation INCREASES with increasing R_{DS(on)}.
Switching Frequency: Pumping voltage deviation INCREASES with increasing switching frequency when the value of the other error source parameters remain substantially constant.

As those of skill in the art can appreciate, R_{DS(on)} is the resistance between the drain and source of a MOSFET when it is driven on (conducting) with a specified gate-source (V_{GS}) voltage. R_{DS(on)} is a parameter readily found on specification datasheets for power MOSFETs.

In order to aid in understanding the various aspects of the embodiments, a comparison will be made of a supply pumping voltage magnitude in a Class-D amplifier application without the various aspects of the embodiments as shown in FIG. 1 (i.e., without the use of HBRBC 100). In the absence of HBRBC 100, Equations 8A and 8B shown in FIG. 8 define the expected magnitude of the rail voltage deviation due to supply pumping. FIG. 8 illustrates a series of calculations regarding an approximation for power supply pumping using a conventional Class-D Amplifier using a half-bridge power stage. Rail voltage deviation is a function of rail capacitance, rail voltage, load impedance, as well as audio signal amplitude and frequency. The following reference will aid a person having ordinary skill in the art in understanding the aspects of the embodiments, but in no way should be taken, and is not meant to be taken, as an admission that the same discloses novel and non-obvious aspects of the embodiments, and is hereby incorporated in its entirety by reference: “Maxim Integrated (ADI) TUTORIAL 4260 Avoid Overvoltage Stresses by Minimizing Power Supply Pumping on Single-Ended Output, Class D Audio Amplifiers Apr. 16, 2010.”

The same parameters will be used in the calculations in FIG. 8 as were used in the calculations of FIG. 5 (e.g., supply rails=+/−100V). Equation (8B) in FIG. 8 yields worst-case pumping when the amplified signal is at a peak voltage of (2/π)×Vdd=0.637×100=63.7V. We now calculate a load impedance that will cause a load current of 10 A peak to flow, so that we can compare the results to the results calculated above (FIG. 5) in regard to the aspects of the embodiments. The peak load current occurs when the signal amplitude is at its peak, which is −63.7V. Therefore, the load impedance at peak output voltage and peak load current is 63.7V/10 A=6.37 ohms. Now, we will turn to the rail capacitance.

According to aspects of the embodiments, HBRBC 100 as shown and described herein is substantially insensitive to rail capacitance. As long as the power supply that is responsible for regulating the output voltage has tight enough load regulation characteristics and control loop frequency response, it will be able to maintain the rail voltage independently of the rail capacitance (within the stability limits of the power supply's feedback loop) i.e., there will be some minimum rail capacitance required to stabilize the power supply's feedback loop. For this example, we will assume a rail capacitance on each of the positive and negative supply rails of about 100 uF. These values are then inserted into Equation (8B) in FIG. 8 which yields a magnitude of the rail pumping voltage change (ΔV_{DD(max)} or ΔV_{SS(max)}) of about 39.76V. This means, in the absence of rail pumping mitigation, as provided by HBRBC 100 according to aspects of the embodiments, the peak value of the positive rail voltage supply will increase from 100V to 139.76V due to rail pumping. In comparison, use of HBRBC 100 according to aspects of the embodiments yields a peak value of the positive rail voltage supply of only about 105.12V, which demonstrates a dramatic improvement (decreased pumping voltage magnitude).

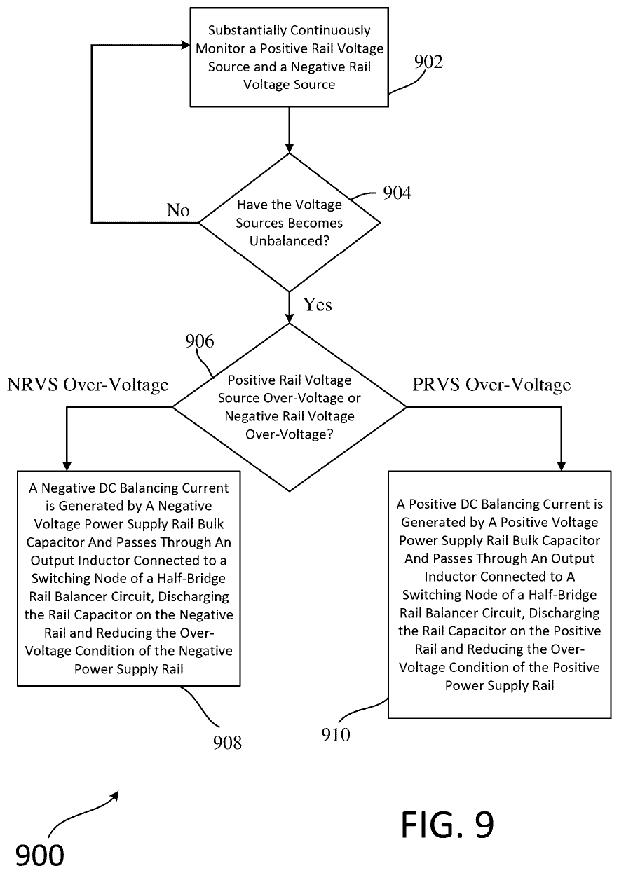

FIG. 9 illustrates a flowchart of method 900 for operating HBRBC 100 according to aspects of the embodiments. As those of skill in the art can appreciate, the steps of method 900, which pertains to the operations of HBRBC 100, are representative of actions taken and performed by that circuit, and as such are not true “steps” as in the sense of a computer program or routine, but are steps in the sense as circuit conditions that occur as a result of other circuit conditions. Those of skill in the art can appreciate, that the “steps” of method 900 are not the result of a routine, algorithm, program, or computer application, stored in memory, and executed by one or more processors. Further, those of skill in the art will understand that the “steps” of method 900 are the result of substantially instantaneous actions and reactions of circuit elements—transistors, capacitors, resistors—and the like, and thus will occur at or near the speed of light, depending on circuit conditions (e.g., capacitors and inductors charging and discharging, and transistors changing state levels, and so on). Nonetheless, the steps of method 900 do occur in the sense that reactions in the circuit will follow events in a consequential manner, in rail balancer 102 according to aspects of the embodiments.

Method 900 begins with step 902 in which HBRBC 100 substantially continuously monitors both a positive rail voltage source and a negative rail voltage source for an unbalanced condition. In decision step 904, HBRBC 100 determines whether the voltage sources have become unbalanced. If the sources are not unbalanced (“No” path from decision step 904), method 900 returns to method step 902, and substantially continuously monitors the positive and negative rail supply voltages.

If the sources are unbalanced, however (“Yes” path from decision step 904), method 900 proceeds to decision step 906 in which method 900 seeks to determine whether the positive rail voltage source is in an over-voltage condition and the negative rail voltage source is in an under-voltage condition, or is the positive rail voltage source in an under-voltage condition and the negative rail voltage source is in an over-voltage condition. If the power supply voltage sources are such that the negative rail voltage is larger in magnitude than the positive rail voltage, method 900 proceeds to step 908. If the power supply voltage sources are such that the positive rail voltage is larger in magnitude than the negative rail voltage, method 900 proceeds to step 910.

If the power supply voltage sources are such that the negative rail voltage is larger in magnitude than the positive rail voltage, method 900 proceeds to step 908.

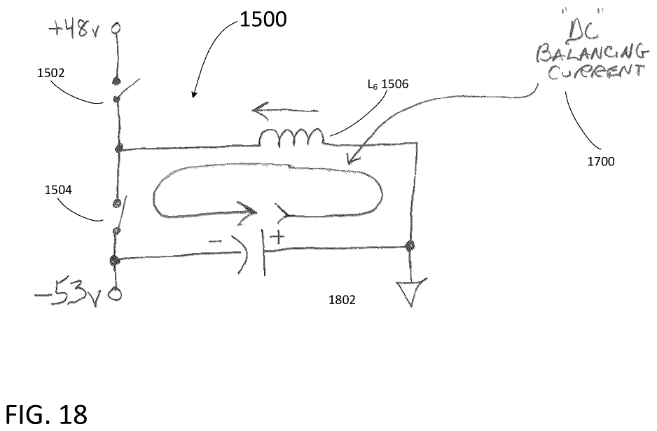

In method step 908, a negative DC balancing current is generated due to the voltage imbalance, as described in greater detail in regard to FIG. 18. The negative DC balancing current is such that it flows from the positive electrode of negative power rail bulk capacitor 1802 through inductor L 1506, and then alternately into the drain of Half-Bridge Rail Balancer Circuit Bottom Transistor Switch (bottom switch SB 1504) and the source of top transistor switch (upper switch ST 1502).

The negative DC balancing current discharges negative power rail bulk capacitor 1802, causing the negative power supply rail voltage to decrease in magnitude. This current will be generated each time the bottom switch SB 1504 is switched on by the 50% duty cycle gate drive signal and will continue to discharge negative power rail bulk capacitor 1802 until the magnitudes of the negative and positive rail voltages are substantially equal.

If the power supply voltage sources are such that the positive rail voltage is larger in magnitude than the negative rail voltage, method 900 proceeds to step 910.

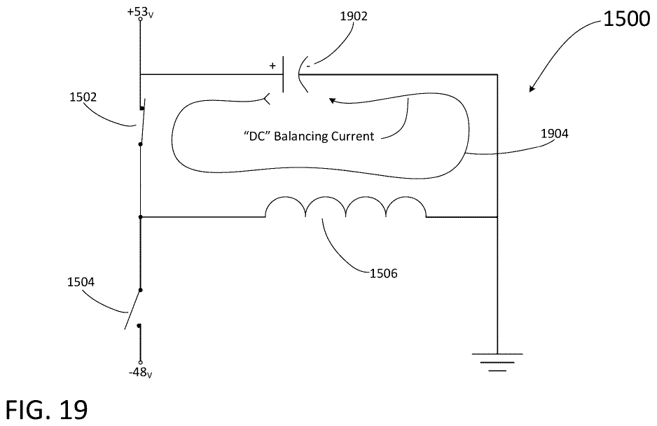

In method step 910, a positive DC balancing current is generated due to the voltage imbalance, as described in greater detail in regard to FIG. 19. The positive DC balancing current is such that it flows from positive power rail bulk capacitor 1902 through inductor L 1506 and alternately into the drain of first transistor (top switch S_{T} 1502, and the drain of the bottom transistor (bottom switch S_{B} 1504). The positive DC balancing current discharges positive power rail bulk capacitor 1902, causing the positive power supply rail voltage to decrease in magnitude. This current will be generated each time the top switch S_{T} 1502 is switched on by the 50% duty cycle gate drive signal and will continue to discharge positive power rail bulk capacitor 1902 until the magnitudes of the negative and positive rail voltages are substantially equal.

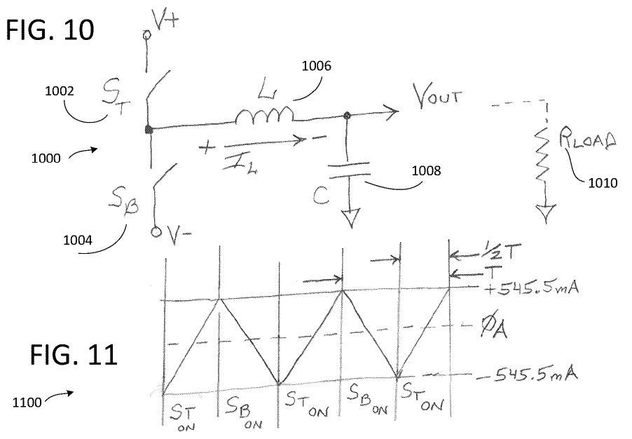

Attention is now directed to FIGS. 10-14, which illustrate the operation of a typical Half-Bridge Class-D Power Stage Amplifier 1000 using bipolar “split” power supply rails, according to aspects of the embodiments, as well as its operational waveforms under two different operating conditions. This information is provided so that those skilled in the art can understand how a Class-D amplifier having this power stage topology, creates power supply rail pumping in the first place, and therefore needs and will benefit from the rail balancing action provided by the inventive circuit.

FIG. 10 illustrates a simplified diagram of Half-Bridge Class-D Power Stage Amplifier 1000 using bipolar “split” power supply rails used in a Class-D Amplifier according to aspects of the embodiments. FIG. 11 illustrates current waveform 1100 formed through Series Inductor L1 (1006) used in said amplifier's Half-Bridge Class-D Power Stage, when said stage is operating at “idle” producing 0V audio output voltage waveform, and switching with a 50% duty cycle—according to aspects of the embodiments.

The switching transistors in FIG. 10 consists of top switch S_{T} in Half-Bridge Class-D Power Stage Amplifier 1000 (top switch S_{T}) 1002 and bottom switch S_{B} in Half-Bridge Class-D Power Stage Amplifier 1000 (bottom switch S_{B}) 1004—as those of skill in the art can appreciate, transistors can operate as switches, and so in this simplified illustration, switches have been used in place of transistors. These transistors (top switch S_{T} 1002 and a bottom switch S_{B} 1004) drive an L-C-R filter comprised of a series inductor L1 1006, Shunt Capacitor used in Half-Bridge Class-D Power Stage Amplifier 1000 (shunt capacitor) 1008 and shunt load resistance (shunt load R_{LOAD}) 1010. The 2 transistors of the half-bridge are always driven by signals with opposite phase, such that when one transistor is ON (e.g., top switch S_{T} 1002), the other transistor (bottom switch S_{B} 1004) is OFF. This prevents both switches from ever being ON at the same time, which would present a damaging short circuit across the power supply rails (V+, V−). When the amplifier is at idle, producing zero output voltage at V_{OUT}, the switches are EACH being driven at exactly about 50% duty cycle. In this mode, the voltage impressed across series inductor L1 1006 is +48V during the ON-TIME of S_{T} and −48V during the ON-TIME of S_{B}. FIG. 11 shows the current waveform 1100 through series inductor L1 1006 at 50% Duty Cycle. Using the Equation (05) below, the change in current (di) is calculated during each of these ON-TIMES.

$${V}_{L} = L \frac{{d}_{i}}{{d}_{t}} ; or {d}_{i} = \frac{{V}_{L} \times {d}_{t}}{L} \qquad Eq . ( 05 )$$

### With . . .

f_{SWX}=1 MHz;
T=1 μsec (T/2=500 nsec);
L1=22 μH;
V+=48 VDC; and
V−=−48 VDC . . . then

$${di}_{{ST}_{ON}} = \frac{48 \times 500 n sec}{22 μH} ; or \qquad Eq . ( 06 )$$

$${di}_{{ST}_{ON}} = 1.091 A$$

It can be seen that if the ON-TIMES of the top switch S_{T} 1002 and the bottom switch S_{B} 1004 are equal, and the voltage magnitude across series inductor L1 1006 is equal for each of the ON-TIMES, then the current ramp up (di) during the on-time of top switch S_{T}1002 will exactly equal the current ramp down (di) during the on-time of bottom switch S_{B} 1004. The current in series inductor L1 1006 will be a triangular ramp waveform centered at OA DC. Therefore, there will be no net DC current flowing through series inductor L1 1006.

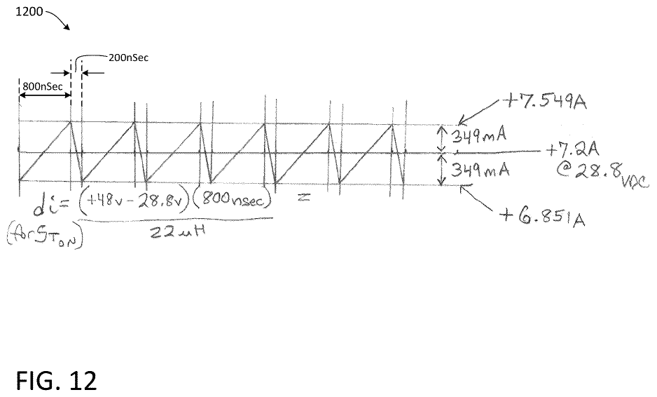

Attention is now directed to FIG. 12, which illustrates a current waveform formed through the inductor L1 of Half-Bridge Class-D Power Stage Amplifier 1000 shown in FIG. 10 when Half-Bridge Class-D Power Stage Amplifier 1000 experiences an eighty percent duty cycle input signal according to aspects of the embodiments.

In this case the duty cycle of Half-Bridge Class-D Power Stage Amplifier 1000 varies away from 50%, as it would if a Class-D amplifier were producing a varying audio signal at V_{OUT}. FIGS. 12-14 illustrate waveforms and behavior for the same Half-Bridge stage, assuming the top switch S_{T} 1002 is ON for 80% of the switching period, and bottom switch S_{B} 1004 is on for 20% of the switching period. As discussed above, this example assumes a switching frequency of 1 MHz (i.e. a switching period of 1 usec) and inductor value=22 uH for series inductor L1 1006.

Thus, t_{ON} of S_{T}=0.8×1 μsec=800 nsec; and t_{ON} of S_{B}=0.2×1 μsec=200 nsec.

Then,

$${V}_{Out} = \frac{( {800}_{nsec} x {48}_{V} ) + ( {200}_{nsec} x - {48}_{V} )}{{1}_{μ sec}} = {28}_{VDC} \qquad Eq . ( 07 )$$

Equation (07) above shows that this duty cycle timing (80%) will produce an output voltage of +28.8 VDC. If shunt load R_{LOAD} 1010 is 4 ohms, this will produce an output DC current of +7.2 A from the Half-Bridge Class-D Power Stage Amplifier 1000 (V=IR; or I=V/R; =28.8/4).

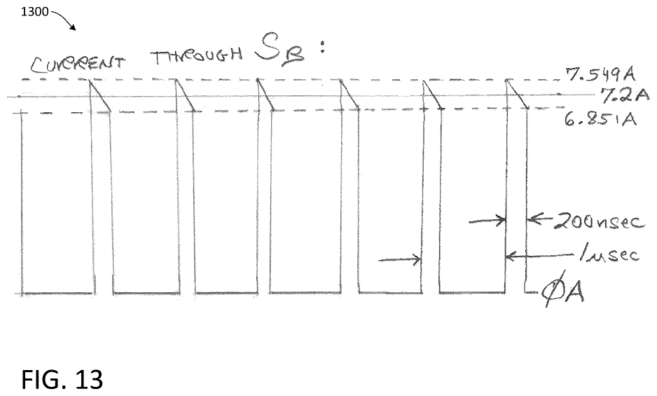

FIG. 12 shows current waveform 1200 through series inductor L1 1006 at 80% duty cycle. When top switch S_{T} 1002 is ON, current will ramp up from +6.851 A to +7.549 A, and when bottom switch S_{B} 1004 is on, current will ramp down from +7.549 A to +6.851 A. The average value of this current (the DC value) is therefore 7.2 A. Attention is now directed to FIG. 13. FIG. 13 shows the current flowing in bottom switch S_{B} 1004 under these same conditions.

FIG. 13 illustrates current waveform 1300 flowing through bottom switch S_{B} 1004 of Half-Bridge Class-D Power Stage Amplifier 1000 as shown in FIG. 10 when the Class-D amplifier experiences an eighty percent duty cycle input signal according to aspects of the embodiments. In FIG. 13, pulses of current flow during the 20% ON-TIME of the bottom switch S_{B}. The average DC value for this current, as shown below in Equation (09), is 1.44 A.

$${I}_{DC} = \frac{( {7.2}_{A} ) \times ( {200}_{nsec} )}{{1}_{μ sec}} = 1.44 {A}_{DC} \qquad Eq . ( 09 )$$

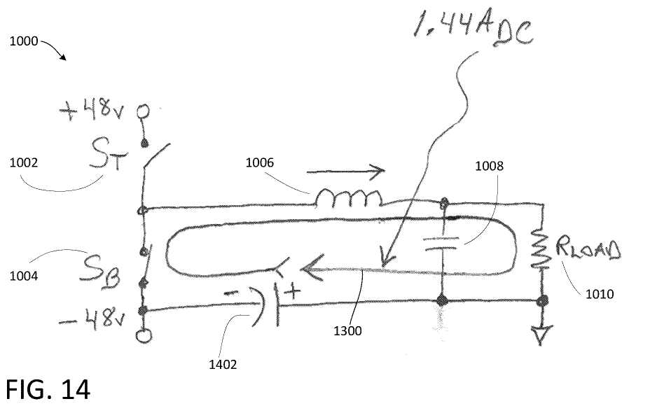

FIG. 14 illustrates current waveform 1300 of FIG. 13 flowing through negative power supply rail bulk capacitor (NPSR bulk capacitor) 402 on a negative power supply rail of the Class-D amplifier as well as through switch S_{B} 1004 according to aspects of the embodiments. This current is in a direction such that it will cause the voltage on NPSR bulk capacitor 1402 to increase. Thus, the negative rail voltage is being pumped-up by the Class-D operation.

The amplitude of the voltage pumping increases as:
Output Current Increases (i.e. greater audio signal amplitude and lower values of load resistance);
Output Audio Frequency Decreases (higher duty cycles are sustained for longer periods (i.e. 50 msec for a 20 Hz audio signal); and
The capacitance value of NPSR Bulk rail capacitor 1402 decreases.

It has therefore been shown how Class-D Half-Bridge circuitry creates the rail voltage supply pumping problem; aspects of the embodiments use this knowledge to realize a similar Half-Bridge circuit, shown in FIGS. 1-9 (rail balancer 102), and 15-18 (a simplified schematic version of rail balancer 102, denoted rail balancer 1500), to counteract the effects of Class-D supply pumping according to aspects of the embodiments.

FIG. 15 is a simplified diagram of half-bridge rail balancing circuit (rail balancer circuit) 1500 of FIGS. 1 and 2 according to aspects of the embodiments.

Rail balancer circuit 1500 is similar to Half-Bridge Class-D Power Stage Amplifier 1000 shown in FIG. 10, and previously discussed, with the principal difference being that the far end of inductor 1506 is connected to ground (0V) in rail balancer circuit 1500, instead of to shunt capacitor 1008 and shunt load R_{LOAD} 1010, as it is in the Class-D circuit shown in FIG. 10. Another key difference is that the duty cycle of top switch S_{T} 1502 and bottom switch S_{B} 1504 in rail balancer circuit 1500 is substantially fixed at about 50%, whereas the duty cycle of Half-Bridge Class-D Power Stage Amplifier 1000, must vary over a wide range (from close to 0% to close to 100%), in order to produce the full range of audio output voltage (V_{OUT}), ranging in voltage from the negative rail voltage to the positive rail voltage.

Equation (09) above shows that, given a fixed value of inductance (L), the ramp up or ramp down of current in the inductor depends on both the voltage impressed across the inductor (V_{L}) and the time duration (dt) that that current is impressed across the inductor. In the case of the Class-D stage, balanced supply rails were assumed, and ramp-up and ramp-down current was dependent on dt.

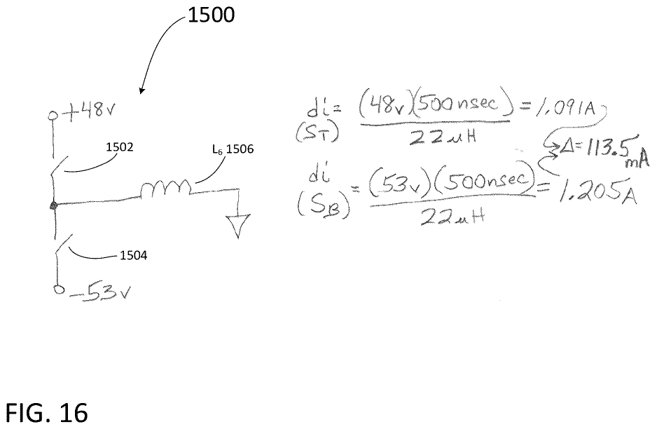

In the Rail Balance case (FIG. 15, and rail balancing circuit 1500), dt is fixed, and the ramp-up and ramp-down of current is dependent on the value of the rail voltages. FIG. 16 and the two Equations below, Equations (21) and (22), illustrate the difference in ramp-up and ramp-down currents when there is an imbalance in the rail voltages (+48V and −53V in the example).

FIG. 16 illustrates the half-bridge rail balancing circuit of FIG. 15 when there is an imbalance in the power rail voltages, i.e., an absolute magnitude of the negative power rail voltage is larger than that of the positive power rail voltage according to aspects of the embodiments.

$${di}_{{ST}_{ON}} = \frac{{48}_{V} \times {500}_{nsec}}{22 μH} = 1.091 A \qquad Eq . ( 10 )$$

$${di}_{{SB}_{ON}} = \frac{{53}_{V} \times {500}_{nsec}}{22 μH} = 1.205 A \qquad Eq . ( 11 )$$

The difference between the two is 1.205-1.091=113.5 mA.

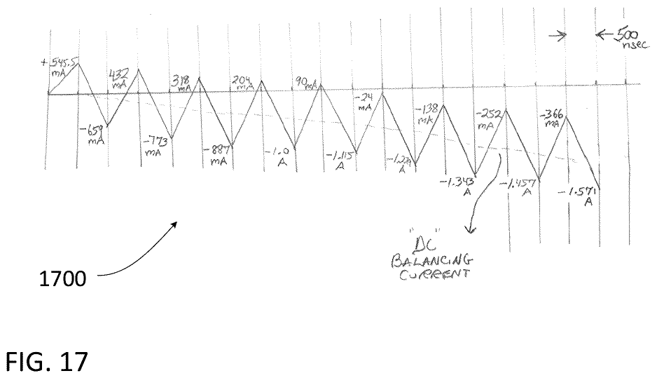

The ramp up current in the above example is 1.091 A, while the ramp down current is 1.205 A. This represents a difference (delta) of 113.5 mA. The 113.5 mA builds up on each switching cycle at the 1 MHz switching frequency. This difference current adds to a net DC current on each subsequent switching cycle. That is, 113.5 mA after the first cycle, then 227 mA on the next cycle, and so on. FIG. 17 illustrates how quickly this small delta current can add up to a significant DC current. Each time there is a negative going current, the peak value—negative in this case—increases negatively by 113.5 mA.

FIG. 17 illustrates DC balancing current 1700 formed through an output inductor L of the half-bridge rail balancing circuit shown in FIG. 15 when the negative power supply rail is greater in magnitude then the positive power supply rail according to aspects of the embodiments. In FIG. 17, DC balancing current 1700 is generated when the switching signal to the two switches ST and SB is a fifty percent duty cycle signal and there is the imbalance in the power rail voltages as shown in FIG. 16 according to aspects of the embodiments.

At the end of the first half positive going cycle, the current increases to 545.5 mA (because there is only one half of the total time the current increases at the very beginning; (1.091/2=545.5 mA). Then, the current deceases by 1.205 A to −659 mA; then, it increases 1.091 A, to a positive value of 482 mA; then decreases by 1.205 A to −779 mA, and so on. On each cycle, the net DC current—the “DC balancing current (the dashed line in FIG. 17)—is decreasing linearly by −113.5 mA. Considering that at 1 MHz, the cycle switches every 500 nsec, it will not take very long for a significantly large balancing current to form which will discharge the overvoltage on the negative rail capacitors, driving the rail voltages back to their equal-voltage condition. The reciprocal situation will occur for a positive rail overvoltage condition. The balancing current formed by a higher positive rail voltage will flow in a direction to discharge the positive rail capacitor, reducing its voltage, and driving the rails back to their equal-voltage condition.

FIG. 17 shows the increase over just 9 switching cycles (9 usec). FIG. 18 shows the direction of the net DC current developed due to the imbalance in the positive and negative supply rail voltages in this example according to aspects of the embodiments. It shows that the current flows in a direction that will discharge negative power rail bulk capacitor 1802 on the negative supply rail—in this case—because it has the higher voltage magnitude, decreasing that rail voltage.

FIG. 19 illustrates a current waveform flowing through the bulk capacitor on the positive power supply rail of the Class-D amplifier according to aspects of the embodiments. In this case, the positive rail voltage has a higher magnitude than the negative rail voltage. DC balancing current flows 1904 in a direction such that the supply voltage imbalance that originally caused the net DC current flow is driven towards balance according to aspects of the embodiments. As those of skill in the art can now appreciate, the aspects of the embodiments illustrate an inherent negative feedback mechanism. FIG. 19 shows that the current flows in a direction that will discharge positive power rail bulk capacitor 1902 on the positive supply rail, because it has the higher voltage magnitude, decreasing that rail voltage.

The disclosed embodiments provide systems, methods, and modes for mitigating over-voltage situations in Class-D amplifiers. It should be understood that this description is not intended to limit the embodiments. On the contrary, the embodiments are intended to cover alternatives, modifications, and equivalents, which are included in the spirit and scope of the embodiments as defined by the appended claims. Further, in the detailed description of the embodiments, numerous specific details are set forth to provide a comprehensive understanding of the claimed embodiments. However, one skilled in the art would understand that various embodiments may be practiced without such specific details.

Although the features and elements of aspects of the embodiments are described being in particular combinations, each feature or element can be used alone, without the other features and elements of the embodiments, or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

The above-described embodiments are intended to be illustrative in all respects, rather than restrictive, of the embodiments. Thus, the embodiments are capable of many variations in detailed implementation that can be derived from the description contained herein by a person skilled in the art. No element, act, or instruction used in the description of the present application should be construed as critical or essential to the embodiments unless explicitly described as such. Also, as used herein, the article “a” is intended to include one or more items.

All United States patents and applications, foreign patents, and publications discussed above are hereby incorporated herein by reference in their entireties.

### INDUSTRIAL APPLICABILITY

To solve the aforementioned problems, the aspects of the embodiments are directed towards systems, methods, and modes for mitigating over-voltage situations in Class-D amplifiers.

### Alternate Embodiments

Alternate embodiments may be devised without departing from the spirit or the scope of the different aspects of the embodiments.

What is claimed is:

1. A high voltage rail balancer circuit, for use in a class D amplifier, adapted to sense an imbalance between a positive high voltage power supply and a negative high voltage power supply, comprising:
a first N-channel metal oxide semiconductor field effect transistor switch (first MOSFET switch) comprising a source terminal electrically connected to the positive high voltage power supply;
a second N-channel metal oxide semiconductor field effect transistor switch (second MOSFET switch) comprising a source terminal electrically connected to the negative high voltage power supply;
a first resistor-diode circuit;
a second resistor-diode circuit;
a three-winding transformer adapted to receive a substantially equal duty cycle switching signal and which is further adapted to
simultaneously drive the first MOSFET switch to a conducting state and to drive the second MOSFET switch to a non-conducting state, and to
simultaneously drive the second MOSFET switch to a conducting state and to drive the first MOSFET switch to a non-conducting state, and wherein
the first resistor-diode circuit is adapted to change the first MOSFET switch from a conducting state to a non-conducting state faster than the second MOSFET switch can change from a non-conducting state to a conducting state, and
the second resistor-diode circuit is adapted to change the second MOSFET switch from a conducting state to a non-conducting state faster than the first MOSFET switch can change from a non-conducting state to a conducting state,
such that cross conduction between the first and second MOSFET switches is substantially prevented.

2. A high voltage rail balancer circuit, for use in a class D amplifier, adapted to sense an imbalance between a positive high voltage power supply and a negative high voltage power supply, comprising:
a first N-channel metal oxide semiconductor field effect transistor switch (first MOSFET switch) comprising a source terminal electrically connected to the positive high voltage power supply;
a second N-channel metal oxide semiconductor field effect transistor switch (second MOSFET switch) comprising a source terminal electrically connected to the negative high voltage power supply;
a first resistor-diode circuit;
a second resistor-diode circuit;
a three-winding transformer adapted to receive a substantially equal duty cycle switching signal and which is further adapted to
simultaneously drive the first MOSFET switch to a conducting state and to drive the second MOSFET switch to a non-conducting state, and to
simultaneously drive the second MOSFET switch to a conducting state and to drive the first MOSFET switch to a non-conducting state; and
a rail-balancing over-current sense circuit electrically connected to both a source terminal of the first MOSFET switch and a drain terminal of the second MOSFET switch, wherein the rail-balancing over-current sense circuit is adapted to generate a voltage that is sensed by an over-current protection circuit to determine an over-voltage condition from either the positive high voltage power supply or the negative high voltage power supply.

3. The high voltage rail balancer circuit according to claim 2, wherein the rail-balancing over-current sense circuit comprises:
series-connected inductor-resistor wherein
a first terminal of the inductor is electrically connected to both a source terminal of the first MOSFET switch and a drain terminal of the second MOSFET switch, and
the second terminal of the inductor is connected to a first terminal of current-sensing resistor, and wherein
a second terminal of the current-sensing resistor is electrically connected to circuit ground, and wherein
the series-connected inductor-resistor is adapted to generate a voltage across the current sensing resistor that is sensed by the over-current protection circuit, to determine an over-current condition in the first or second MOSFET switch that is caused by over-voltage condition from either the positive high voltage power supply or the negative high voltage power supply.

4. The high voltage rail balancer circuit according to claim 3, wherein the over-current protection circuit comprises:
a negative over-current comparator with a first positive input and a first negative input;
a positive over-current comparator with a second positive input and a second negative input;
a negative voltage resistor divider network adapted to provide a negative voltage threshold to the first negative input of the negative over-current comparator;
a positive voltage resistor divider network adapted to provide a positive voltage threshold to the first positive input of the positive over-current comparator, and wherein
the voltage across the current sensing resistor of the series-connected inductor-resistor is received at the positive input of the positive over-current comparator and causes the positive over-current comparator to output an over-current protection signal that shuts down the high voltage rail balancer circuit when the received voltage is higher than the positive voltage threshold, and wherein
the voltage across the current sensing resistor of the series-connected inductor-resistor is received at the negative input of the negative over-current comparator and causes the negative over-current comparator to output an over-current protection signal that shuts down the high voltage rail balancer circuit when the received voltage is lower than the negative voltage threshold.

5. A method for operating a high voltage rail balancer circuit, the circuit being adapted to sense an imbalance between a positive high voltage power supply and a negative high voltage power supply, for use in a class D amplifier, comprising:
driving, in a complementary manner, a first N-channel metal oxide semiconductor field effect transistor switch (first MOSFET switch) having a source terminal electrically connected to the positive high voltage power supply and a second N-channel metal oxide semiconductor field effect transistor switch (second MOSFET switch) having a source terminal electrically connected to the negative high voltage power supply by a three-winding transformer that receives a substantially equal duty cycle switching signal, wherein
the first MOSFET switch is simultaneously driven to a conducting state while the second MOSFET switch is driven to a non-conducting state, and then
the second MOSFET switch is simultaneously driven to a conducting state while the first MOSFET switch is driven to a non-conducting state;
switching the first MOSFET switch by a first resistor-diode circuit from the conducting state to the non-conducting state faster than the second MOSFET switch changes from the non-conducting state to the conducting state; and
switching the second MOSFET switch by a second resistor-diode circuit from the conducting state to the non-conducting state faster than the first MOSFET switch changes from the non-conducting state to the conducting state,
such that cross conduction between the first and second MOSFET switches is substantially prevented.
